(19) United States
(12) Patent Application Publication
(10) Pub. No.: US 2012/0288643 A1
(43) Pub. Date: Nov. 15, 2012

(54) Multi-Zone Chuck

(75) Inventor: Robert Wayne Donis, Washougal, WA (US)

(73) Assignee: LSI CORPORATION, Milpitas, CA (US)

(21) Appl. No.: 13/554,730

(22) Filed: Jul. 20, 2012

Related U.S. Application Data
(62) Division of application No. 11/063,788, filed on Feb. 22, 2005, now abandoned.

(51) Int. Cl. C23C 16/44

(52) U.S. Cl. 427/585

(57) ABSTRACT

A method for affecting film growth on a substrate during a deposition process includes steps of: applying a first voltage or current to a first zone of a chuck adapted to hold the substrate in position, the film growth on at least a portion of the substrate proximate the first zone being affected as a function of a level of the first voltage or current; and applying a second voltage or current to a second zone of the chuck, the film growth on at least a portion of the substrate proximate the second zone being affected as a function of a level of the second voltage or current.

### CROSS-REFERENCE TO RELATED APPLICATIONS

This application is a divisional of pending U.S. patent application Ser. No. 11/063,788 filed on Feb. 22, 2005, the disclosure of which is incorporated herein by reference in its entirety for all purposes.

### BACKGROUND

A. Technical Field

The present invention relates generally to the field of semiconductor wafer fabrication, and more particularly, to providing more uniform depositions on semiconductor wafers.

B. Background of the Invention

During the manufacturing of semiconductor devices, including integrated circuits or microchips, metal or dielectric films are deposited onto a wafer. These films range from highly conductive metal films, such as aluminum, tungsten, and copper, to dielectric films, such as silicon-dioxide, silicon nitride, and various other films having low dielectric (low k) values. The metal and dielectric films may be deposited using any of a number of deposition chambers and different processes, such as Chemical Vapor Deposition (CVD) and Plasma Chemical Vapor Deposition (PCVD).

During a typical process, a solid film (metal or dielectric) is formed on a wafer substrate by the reaction of vapor-phase chemicals or reactants that contain the required constituents. Typically, the reactant gases are introduced into a reaction chamber and are decomposed or reacted at a heated surface to form a thin film. During this process, an electrostatic chuck is used to hold the wafer in position in the deposition chamber. The chuck holds the wafer in position by electro-static forces, which is accomplished by applying a voltage to the entire chuck.

Due to uneven topography of the wafer, possibly resulting from previous deposition cycles or other manufacturing processes, reactants may grow uneven layers onto the surface of the wafer. Furthermore, the geometric layout of the wafer may create areas of uneven deposition.

Uneven film deposition may require additional processing to make the wafer layer even. Additional processing creates added costs and waste. Furthermore, additional processes, such as chemical mechanical polishing or planarization, are limited in their ability to correct unevenness of a wafer surface. Thus, uneven film deposition can result in increased costs due to costs of additional processing and loss of yield.

### SUMMARY OF THE INVENTION

Thus, an object of the present invention is to provide systems and methods that allow for more uniform growth of films on substrates.

In an embodiment of the present invention, a chuck for holding a substrate in a deposition chamber comprises at least two electrically distinct zones, wherein voltages or currents may be applied to each of the zones. In an embodiment, a controller provides the ability to control the timing, magnitude, and polarity of the voltage or current applied to each of the zones. The voltage or current applied to one or more zones may affect the growth of a film on a substrate by attracting or repelling reactants to a portion of the substrate.

An embodiment of the present invention comprises a method for affecting film growth on a substrate during a deposition process. In one embodiment, the method comprises placing a substrate on a chuck, wherein the chuck comprises at least two zones. Each of the zones in the chuck is electrically distinct from each other so that a voltage or current may be applied individually to each zone. A voltage or current is applied to one or more zones to affect the growth of a film on a substrate by attracting or repelling reactants to a portion of the substrate. In an alternate embodiment, the method may further comprise the step of varying the voltage or current applied to at least one of the zones during a deposition process.

### BRIEF DESCRIPTION OF THE DRAWINGS

Reference will be made to embodiments of the invention, examples of which may be illustrated in the accompanying figures. These figures are intended to be illustrative, not limiting. Although the invention is generally described in the context of these embodiments, it should be understood that it is not intended to limit the scope of the invention to these particular embodiments.

FIG. 1 is a top view of a chuck with a plurality of circular electrical zones.

FIG. 2 illustrates a partial profile of a reaction chamber with reactants present and a wafer placed on an embodiment of a multi-zone chuck.

FIG. 3 is a top view of a chuck with a plurality of radial electrical zones.

FIG. 4 is a top view of a chuck with a plurality of parallel electrical zones.

FIG. 5 is a top view of a chuck with a plurality of electrical zones.

FIG. 6 is a block diagram of an embodiment of a multi-zone chuck functionally connected to a voltage controller.

FIG. 7 is a flow chart illustrating an embodiment of a method for creating a wafer by varying the electrical profile of a multi-zone chuck.

### DETAILED DESCRIPTION OF THE PREFERRED EMBODIMENTS

In the following description, for purposes of explanation, specific details are set forth in order to provide an understanding of the invention. It will be apparent, however, to one skilled in the art that the invention can be practiced without these details. Furthermore, one skilled in the art will recognize that embodiments of the present invention, described below, may be performed in a variety of ways and using a variety of mediums, including software, hardware, or firmware, or a combination thereof. Accordingly, the embodiments described below are illustrative of specific embodiments of the invention and are meant to avoid obscuring the invention.

Reference in the specification to “one embodiment,” “a preferred embodiment,” or “an embodiment” means that a particular feature, structure, characteristic, or function described in connection with the embodiment is included in at least one embodiment of the invention. The appearances of the phrase “in one embodiment,” “in an embodiment,” or the like in various places in the specification are not necessarily all referring to the same embodiment.

Currently, chucks employed in chemical vapor deposition and plasma chemical vapor deposition wafer production processes function to hold the wafer in place during processing. The present invention provides the ability to provide additional functionality by varying electrical zones or regions on the chuck 100.

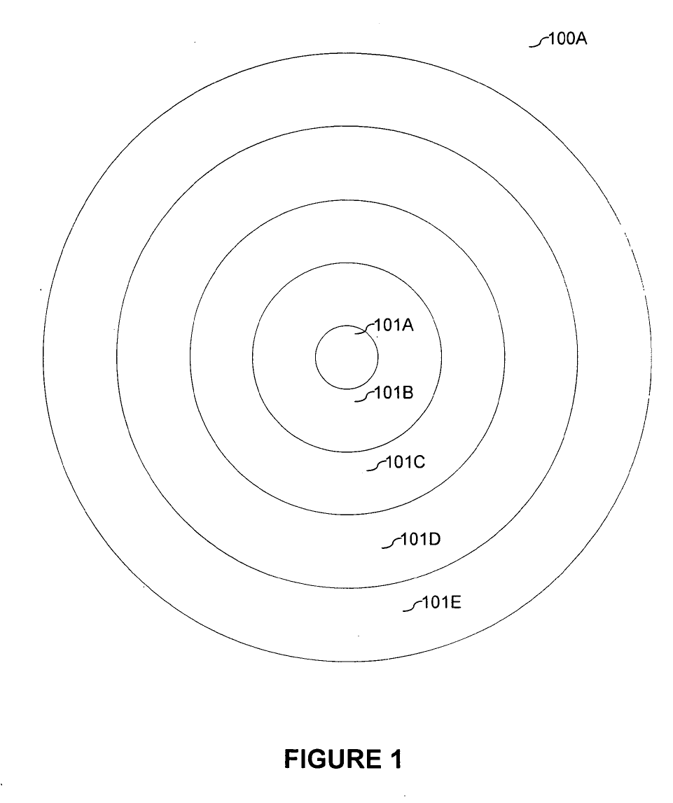

FIG. 1 depicts an embodiment of a multi-zone electrical chuck 100A. Multi-zone chuck 100A comprises a plurality of electrically distinct zones or regions 101. In the embodiment depicted in FIG. 1, chuck 100A is comprised of five electrically distinct zones 101A-101E. Each zone 101A-E is electrically isolated from each other zone, and each zone 101A-101E is capable of being set to a voltage independent of the voltage applied to each of the other zones. For example, each zone may be divided by an insulating material and a conductor attached to each zone may apply the voltage. It should be noted that although each zone is capable of being set to a voltage level different from the other zones, two or more zones may be set to the same voltage.

A chuck 100 with the ability to vary the voltage in different zones allows for greater uniformity to be achieved during a CVD or PCVD process. By changing the voltage level at different zones across the chuck, reactants in the process chamber may be attracted or repelled to regions of the wafer to create a desired deposition profile on the wafer.

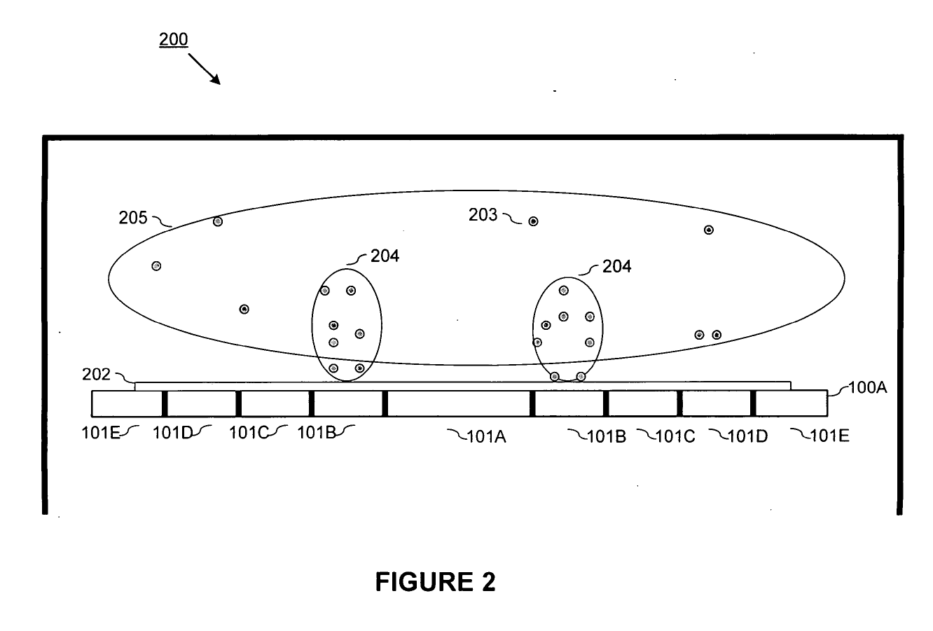

FIG. 2 is an illustration of a side view of part of a reaction chamber 200 with an embodiment of a multi-zone electric chuck 100A holding a wafer substrate 202. In FIG. 2, a reactant gas 203 constituting the chemicals for a film deposition is introduced over wafer 202. Reactant 203 has a general concentration 205 over the surface of wafer 202. As illustrated, there is a higher concentration 204 of the reactant over zone 101B. As discussed with respect to FIG. 1, the multi-zone chuck 100A has the ability to vary the voltages of its different zones.

Each of zones 101A-101E may be biased to different voltage levels according to a desired profile sought to be achieved during the CVD or PCVD process. For example, if the area above zone 101B requires more layer growth on wafer 202 than other areas on wafer 202, zone 101B may be set to a higher voltage than other zones to attract a higher concentration 204 of reactant 203 to the area above zone 101B, including attracting more reactants to the surface of the substrate 202 above region 101B. The voltage level may be set higher or lower than other zones depending on the system configuration, such as the polarity of reactant 203 and whether reactant 203 is to be attracted or repelled from the specified area or portion.

A desired profile may be determined in a number of ways. In one embodiment, sample wafers may be inspected to determine the profile resulting from the manufacturing process. In another embodiment, the desired profile may be determined given the known wafer geographies and/or previous manufacturing processes. In yet another embodiment, the wafer, itself, may be examined to determine its specific profile.

One skilled in the art will recognize that the voltages applied to the various zones 101A-101E need not be held static during the entire CVD or PCVD process. Rather, the voltages may be changed during the process to adjust the rates of film growth during the CVD or PCVD process.

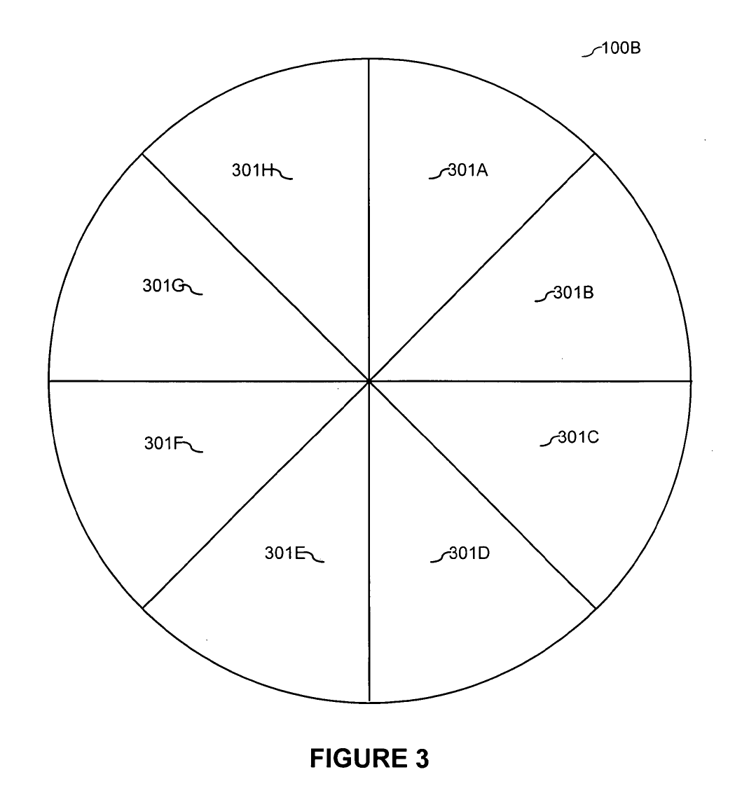

FIG. 3 depicts an alternate embodiment of a multi-zone electric chuck. Chuck 100B possesses a plurality of zones 301A-301H. Each of the zones 301A-301H may be electrically distinct from each other zone. In the embodiment depicted in FIG. 3, zones 301A-301H are pie-shaped sections of chuck 100B.

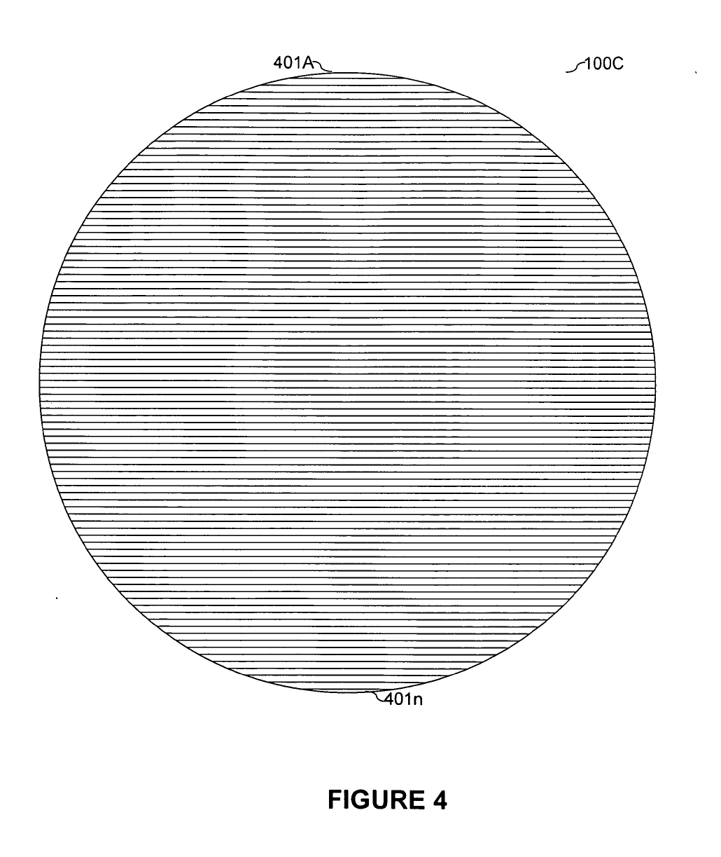

FIG. 4 depicts an alternate embodiment of a multi-zone electric chuck. Chuck 100C possesses a plurality of parallel or substantially parallel zones 401A-401n. Each of the zones 401A-401n may be electrically distinct from each other zone. In the embodiment depicted in FIG. 4, chuck 100C may be configured with a number of zones varying from 2 to n.

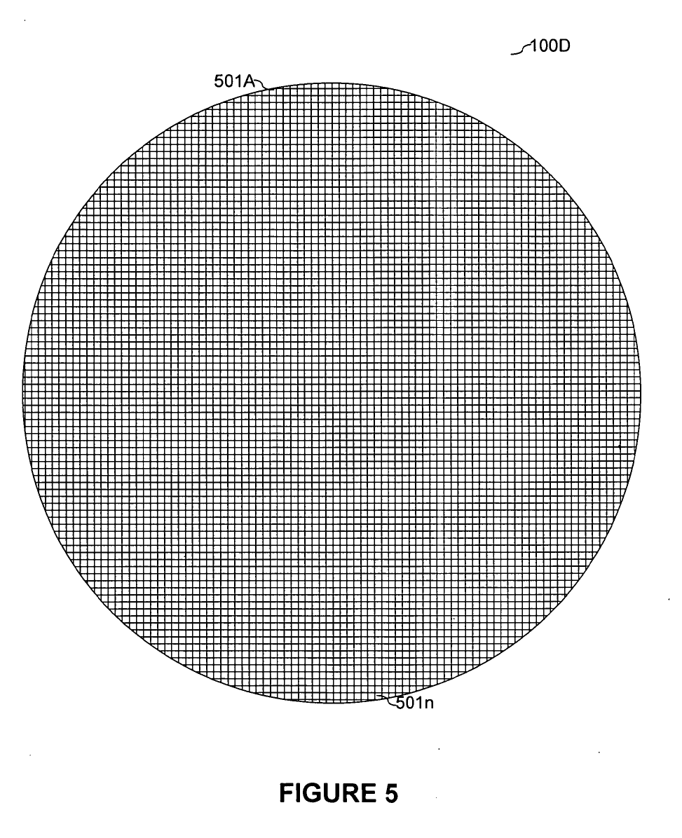

FIG. 5 depicts an alternate embodiment of a multi-zone electric chuck. Chuck 100D possesses a plurality of small zones 501A-501n. Each of zones 501A-501n may be electrically distinct from each other zone. In the embodiment depicted in FIG. 5, chuck 100D may be configured with a number of zones varying from 2 to n. The small zones 501A-501n increase the ability to direct reactants to smaller portions on a wafer. It should be understood with this embodiment, as with each of the embodiments, that the different zones 501A-501n of chuck 100D may be the same size and shape or may be different in size and/or shape.

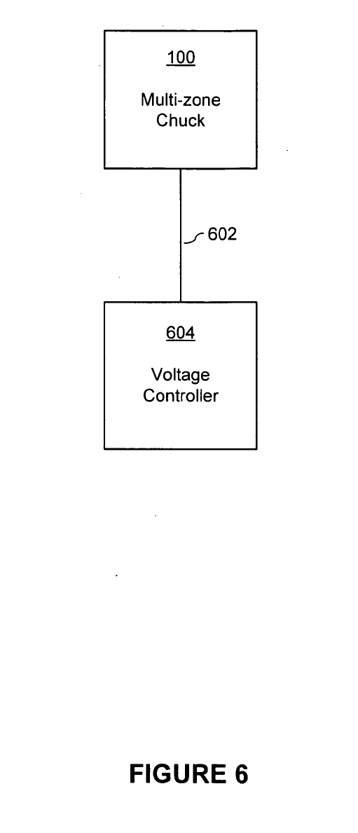

FIG. 6 depicts a block diagram of an embodiment of the present invention comprising a multi-zone chuck 100 functionally connected via connection 602 to a voltage controller 604. It should be noted that where the specification discusses applying and/or controlling voltages to a zone, this also encompasses applying and/or controlling current flow through a zone. For example, in an embodiment, a voltage is applied to a zone by allowing a current to flow through the zone. One skilled in the art will also recognize that voltage controller 604 may be any of a number of devices or combination of devices known for controlling voltage levels or current flows. Furthermore, voltage controller 604 may be implemented in hardware, firmware, software, or any combination thereof. In an embodiment, voltage controller 604 may be a potentiometer, which is under the control of a user. In an alternate embodiment, voltage controller 604 may be a processor or a computer system that controls the voltage levels/current levels of the different zones on a chuck 100. A processor or computer system may also be configured to receive wafer profile information prior to or during the CVD or PCVD process. After receiving the profile information, the system may adjust the voltages/currents applied to the zones of chuck 100 to achieve the desired profile during the CVD or PCVD process.

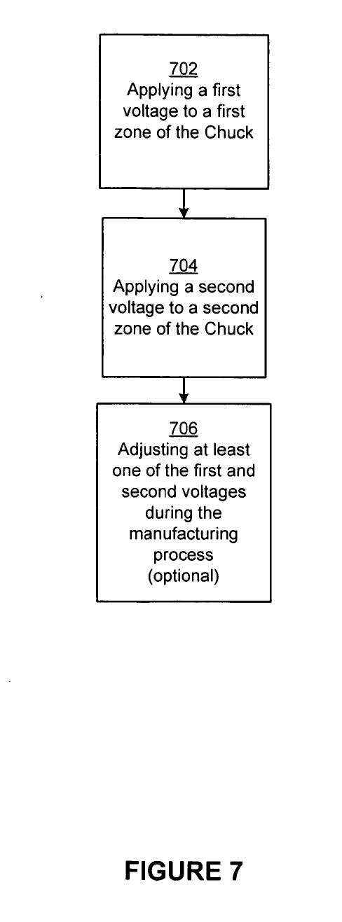

FIG. 7 depicts a flow chart illustrating an embodiment of a method for controlling the film growth on a wafer by varying the electrical profile of a multi-zone chuck. With the wafer positioned on a chuck with at least two electrically distinct zones, a first voltage is applied 702 to a first zone of the multi-zone chuck. A second voltage is applied 704 to a second zone of the multi-zone chuck. Additional voltages may be applied to other zones on the chuck depending on the configuration of the multi-zone chuck and also depending on the desired profile. It should be noted that these voltages may be applied at the same time or at different times during the CVD or PCVD process. It should also be understood that the discussions within this specification of applying a voltage to a zone can include the application of zero, or no voltage, to a zone. In an embodiment, the voltages applied to a zone or zones may be varied or adjusted 206 during the CVD or PCVD process.

The above description is included to illustrate embodiments of the present invention and is not meant to limit the scope of the invention. The scope of the invention is to be limited only by the following claims. From the above discussion, many variations will be apparent to one skilled in the art that would yet be encompassed by the spirit and scope of the present invention.

What is claimed is:

1. A method for affecting film growth on a substrate during a deposition process, the method comprising steps of:
applying a first voltage or a first current to a first zone of a chuck adapted to hold the substrate in position, the film growth on at least a portion of the substrate proximate the first zone being affected as a function of a level of the first voltage or current; and
applying a second voltage or a second current to a second zone of the chuck, the film growth on at least a portion of the substrate proximate the second zone being affected as a function of a level of the second voltage or current.

2. The method of claim 1, wherein the first and second voltages are different voltages.

3. The method of claim 1, wherein the voltage or current applied to at least one of the first and second zones is configured to affect a reactant's concentration near a portion of the substrate.

4. The method of claim 1, wherein the level of voltage applied to at least one of the first and second zones is controlled by controlling a current through the at least one of the first and second zones.

5. The method of claim 1, further comprising varying the level of voltage or current applied to at least one of the first and second zones during at least a portion of the deposition process.

6. The method of claim 1, further comprising varying the level of voltage or current applied to at least one of the first and second zones to thereby create a desired deposition profile on the substrate.

7. The method of claim 1, further comprising controlling a uniformity of the film growth across the substrate by controlling the respective levels of the voltage or current applied to the first and second zones.

8. The method of claim 1, further comprising adjusting a rate of film growth on the substrate by dynamically changing the level of voltage or current applied to at least one of the first and second zones during at least a portion of the deposition process.

9. The method of claim 1, wherein the first and second zones are electrically insulated from one another.

10. The method of claim 1, wherein the levels of first and second voltages are controlled independently of one another.

11. The method of claim 1, further comprising:
receiving a prescribed deposition profile; and
controlling a thickness of film growth on the substrate in accordance with the deposition profile by controlling the level of the voltage or current applied to at least one of the first and second zones during at least a portion of the deposition process.

12. The method of claim 1, wherein the step of applying the first voltage or current is performed concurrently with the step of applying the second voltage or current.

13. A method for affecting film growth on a substrate, the method comprising:
placing the substrate on a chuck, said chuck comprising a plurality of zones, said zones being electrically insulated from each other;
applying a voltage or a current to at least one of the plurality of zones; and
controlling the film growth on at least a portion of the substrate as a function of a level of the voltage or current applied to the at least one of the plurality of zones.

14. The method of claim 13, further comprising the step of applying different voltages to at least two of the plurality of zones during at least a portion of a deposition process.

15. The method of claim 14, wherein the different voltages are concurrently applied to corresponding zones during the deposition process.

16. The method of claim 14, wherein at least two of the different voltages are applied to corresponding zones at different times during the deposition process.

17. The method of claim 13, wherein the voltage applied to at least one of the plurality of zones affects growth of the film on a portion of the substrate.

18. The method of claim 13, wherein the voltage applied to at least one of the plurality of zones is controlled by controlling the current through said zone.

19. The method of claim 13, further comprising the step of varying the voltage applied to at least one of the plurality of zones during a deposition process.

20. The method of claim 13, further comprising:
receiving a prescribed deposition profile; and
controlling a thickness of film growth on the substrate in accordance with the deposition profile by controlling the level of the voltage or current applied to at least one of the plurality of zones during at least a portion of the deposition process.

21. The method of claim 13, further comprising creating a desired deposition profile by varying the level of the voltage or current applied to different zones across the chuck during at least a portion of the deposition process.

22. The method of claim 13, further comprising controlling a uniformity of the film growth across the substrate by controlling respective levels of the voltage or current applied to at least a subset of the plurality of zones across the chuck during the deposition process.
